(19) United States
(12) Patent Application Publication
(10) Pub. No.: US 2008/0278988 A1
(43) Pub. Date: Nov. 13, 2008

(54) RESISTIVE SWITCHING ELEMENT

(76) Inventor: Klaus Ufert, Unterschleissheim (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/746,393

(22) Filed: May 9, 2007

(51) Int. Cl. G11C 11/00; H01C 10/00; H01C 17/00

(52) U.S. Cl. 365/148; 29/621; 338/20

(57) ABSTRACT

According to one aspect, an integrated circuit may comprise a first electrode, a second electrode, and a resistive switching rod extending from the first electrode to the second electrode and being at least partly embedded in a thermal barrier matrix.

### BACKGROUND OF THE INVENTION

The invention generally relates to a resistive switching element.

### SUMMARY OF THE INVENTION

One embodiment of the invention provides an exemplary switching element for reversible switching between an electrically high resistive state and an electrically low resistive state is described. The switching element may comprise two electrode means and at least one resistive switching rod extending between the two electrode means, i.e. the resistive switching rod may connect one of the electrode means with the other one. The at least one resistive switching rod may be arranged between the two electrode means.

### BRIEF DESCRIPTION OF THE DRAWINGS

Details of one or more implementations are set forth in the accompanying exemplary drawings and exemplary description below. Other features will be apparent from the description and drawings, and from the claims.

FIGS. 1A and 1B show a schematic of a first exemplary resistive switching element in a high resistivity state and a low resistivity state, respectively;

FIGS. 2A and 2B show a schematic of another exemplary resistive switching element in a high resistivity state and a low resistivity state, respectively;

FIGS. 3A and 3B show a schematic of yet another exemplary resistive switching element in a high resistivity state and a low resistivity state, respectively;

FIG. 4 shows a current vs. voltage diagram demonstrating exemplary switching processes;

FIG. 5 shows a circuit diagram of an exemplary memory cell comprising a switching element;

FIG. 6 shows a circuit diagram of an exemplary memory device comprising a plurality of non-volatile memory cells;

FIG. 7 shows a cross section of an exemplary memory device;

FIGS. 8A to 8H show an exemplary method of fabricating a switching element; and

FIG. 9 shows an exemplary computer system.

### DETAILED DESCRIPTION OF THE PREFERRED EMBODIMENT

In one aspect, an exemplary switching element for reversible switching between an electrically high resistive state and an electrically low resistive state is described. The switching element may comprise two electrode means and at least one resistive switching rod extending between the two electrode means, i.e. the resistive switching rod may connect one of the electrode means with the other one. In particular, the at least one resistive switching rod may be arranged between the two electrode means.

In one example, the at least one resistive switching rod may be implemented as a string or wire having a first and a second end, where the resistive switching rod may connect the first electrode means via the first end and the second electrode means via the second end. In one aspect the resistive switching rod has a longitudinal extent between the first end and the second end that is greater than a transversal extent of the resistive switching rod, i.e. the resistive switching rod may be longer than wide. In one example the at least one resistive switching rod may extend substantially along a straight line or axis between the first end and the second end. In this example the at least one resistive switching rod may be implemented in a pillar shape. In another example, at least part of the resistive switching rod may be bent. Nevertheless, the resistive switching rod is not limited to an elongated shape. A cross sectional shape of the resistive switching rod may be substantially circular or elongated, such as elliptical, for example. In another example, the resistive switching rod may have a substantially regular or non-regular polygonal cross sectional shape, such as a triangular, rectangular, square, or hexagonal shape, for example. The resistive switching rod, however, is not limited to one of these exemplary cross sectional shapes. In one aspect the cross sectional shape of the resistive switching rod may be substantially constant along the length of the rod. In another aspect the cross sectional shape changes along the length of the resistive switching rod.

In one aspect, the resistive switching rod may exhibit two different stable states, i.e. one high resistive state and one low resistive state, between which the resistive switching rod may be switched reversibly. An electrical resistance ratio of the high resistive state with respect to the low resistive state of the resistive switching rod may, for example, be at least 10. In another example, the ratio of the resistance in the high resistive state with respect to the low resistive state may be at least 100. In one aspect a switching element may be rapidly switchable, for example in the region of the switching times of conventional DRAM/SRAM memory cells or not more than a factor of 10 slower, for example.

In another example, the at least one resistive switching rod may exhibit more than two stable states. Accordingly, the resistive switching rod may exhibit at least a high resistive state, a low resistive state and an intermediate resistive state, for example.

The at least one resistive switching rod may be at least partly embedded in a thermal barrier matrix comprising thermally low conductive material. In particular, the resistive switching rod may be arrange adjacent to or may be at least surrounded or coated by material having a thermal conductivity that is lower than the thermal conductivity of the resistive switching rod.

In one aspect, the resistive switching rod may be switchable by a thermal or thermally assisted switching process such as a switching pulse. For example, an electrical, an optical, and/or a thermal pulse may be applied to the resistive switching rod. The application of such a switching pulse may lead to a heating of at least part of the resistive switching rod. In particular, the resistive state of the resistive switching rod may switch from a high resistive state to a low resistive state or vice versa depending on an applied switching pulse.

In one example, an electrically conductive filament may be formed or dispersed in the resistive switching rod as a result of the applied switching pulse, where the process of formation or breaking of the conductive filament may be thermally triggered or assisted. The electrically conductive filament may comprise metal-metal bonds, electrically conductive metal clusters and/or other electrically conductive bonds or compounds. For example, the electrically conductive filament may comprise electrically conductive metal-nitride bonds or compounds. Various materials, such as solid electrolytes, for example, may be applied for the resistive switching rod. The resistive switching rod may comprise chalcogenides and/or a transition metal oxide, for example. Alternatively or additionally, transition metal oxinitride may be applied for the at least one resistive switching rod. Apparently, also other materials may be applied that support the formation of at least two states having different electrical resistance in the resistive switching rod. Particular examples are described in more detail below.

With the resistive switching rod being at least partly embedded in a thermal barrier matrix, heat diffusion out of the resistive switching rod during a switching pulse may be suppressed, such that switching can be achieved with a low pulse energy and a short switching time.

In one aspect a switching element may comprise two electrode means and a plurality of resistive switching rods each of which extends between the two electrode means, i.e. each of the resistive switching rods may connect one of the electrode means with the other one.

In one aspect the switching element may be implemented as a memory cell such as a non-volatile memory cell, for example. In this aspect, the at least one resistive switching rod may be implemented as a non-volatile resistive storage rod, where each of the stable resistive states of the at least one resistive switching rod may represent a separate non-volatile storage state of the memory cell. Reading the stored information may be achieved by determining the resistance of the at least one resistive storage rod without changing its resistive state, i.e. without deleting the information stored in the cell.

In one aspect, the resistive switching rod may comprise transition metal oxide material (TMO). In another aspect, the resistive switching rod may comprise transition metal oxinitride material (TMOₓN_{y}). Other materials or material compositions may be applied alternatively or additionally. The at least one resistive switching rod may exhibit at least two different resistive states. Switching between these states may, for example occur in response to a current or voltage pulse applied to the switchable medium, such as the transition metal oxinitride material, for example, via the electrode means. In one aspect, the transition metal oxinitride comprises transition metal (TM) material that may form, together with nitrogen (N), at least one electrically conductive compound, i.e. the transition metal implemented in the resistive switching rod, in accordance with this aspect, may form an electrically conductive transition metal nitride, for example. The electrical resistivity of the transition metal nitride may be lower than the electrical resistivity of the applied transition metal oxinitride (TMOₓN_{y}).

In one aspect, the absolute content of oxygen and/or nitrogen in the transition metal oxinitride (TMOₓN_{y}) may depend on the oxidation state of the transition metal. The transition metal oxinitride may appear in a sub-stoichiometric composition, where less oxygen and/or nitrogen is present than in a stoichiometric composition. In one aspect an atomic content ratio between nitrogen and oxygen may be between y/x=0.005 and y/x=0.10, for example. Nevertheless, other concentration of oxygen and/or nitrogen may also be applied.

When applying a sufficiently intense current or voltage pulse to the transition metal oxinitride via electrode means, for example, at least some of the metal-oxide bonds of the transition metal oxinitride may break due to the electric field caused by an applied voltage pulse or due to a heating caused by a current flow in the medium. Heating may, for example, occur locally in the resistive switching rod. In one aspect, the transition metal oxinitride material applied for the resistive switching rod may exhibit an atom or ion mobility within the medium that is higher for nitrogen atoms or ions than for metal atoms or ions, such as the atoms or ions of the transition metal applied for the transition metal oxinitride material. Accordingly, due to the higher mobility of nitrogen, broken metal-oxide bonds may be easier replaced by metal-nitride bonds than by metal-metal bonds. Due to a higher electrical conductivity in the vicinity of the metal-nitride as compared to the metal-oxide bonds, the resistivity of the medium decreased through the breakage of metal-oxide bonds and the formation of metal-nitride bonds. Accordingly, heating of the material through a current pulse or the electrical field caused by an applied voltage may, at least locally, decrease unless a more intense current or voltage pulse is applied.

Therefore, the transition metal oxinitride material may exhibit a self-stabilization at a state where some of the metal-oxide bonds are replaced by metal-nitride bonds causing a lower electrical resistance in their vicinity. This state may represent a non-volatile low resistivity state, or an “ON” state of the switching element, while the state having less metal-nitride bonds and more metal-oxide bonds may be regarded a non-volatile high resistivity state, or an “OFF” state of the switching element. A current or voltage pulse bringing the switching element from the “OFF” state to the “ON” state, as exemplarily described above, may be regarded as a “SET” pulse.

It will be appreciated by the person skilled in the art that alternatively or additionally to the described example also other materials may be applied for the resistive switching rod. Moreover, also other switching pulses comprising thermal pulses, optical pulses, electrical pulses, etc. may be applied within the scope of this description.

Due to a thermal isolation of the resistive switching rod by the thermal barrier matrix, diffusion of heat out of the resistive switching rod during the “SET” pulse is suppressed. Accordingly, a sufficiently high temperature for the intended breakage and reformation of chemical bonds or the rearrangement of atoms or molecules in the resistive switching rod can be achieved with a low pulse energy and within a short pulse duration time. This ensures low power consumption and a long lifetime of the switching device.

In one aspect in a low resistivity state the resistive switching rod may comprise an electrically conductive filament extending at least partly between the at least two electrode means. In the above described example, the electrically conductive filament may be rich of metal-nitrogen bonds, i.e. there may be a higher concentration of metal-nitrogen bonds in the electrically conductive filament than in the rest of the resistive switching rod. In one example the electrically conductive filament may extend continuously from one electrode means to the other electrode means. The electrically conductive filament may serve as a conductance channel between the electrode means, thereby causing the switchable medium to exhibit the “ON” state. In one exemplary aspect, the filament may be at least partly formed as an amorphous structure without a formation of crystalline zones. In one example, the electrically conductive filament may occupy only a small fraction of the resistive switching rod in its diameter or transversal cross section, i.e. the electrically conductive filament may be thinner than the resistive switching rod.

When starting from a low resistivity state, i.e. an “ON” state, and applying a current or voltage pulse having sufficient energy the electrically conductive filament may be electrically or thermally destroyed and the resistive switching rod may return to its initial high resistivity state, i.e. an “OFF” state of the switching element. Such a current or voltage pulse may be regarded as a “RESET” pulse. Due to the low thermal conductivity of the thermal barrier matrix adjacent to at least part of the resistive switching rod diffusion of heat out of the resistive switching rod during the “RESET” pulse is suppressed. Accordingly, a sufficiently high temperature for the intended breakage and reformation of chemical bonds or the rearrangement of atoms or molecules in the resistive switching rod can be achieved with a low pulse energy and within a short pulse duration time. This ensures low power consumption and a long lifetime of the switching device.

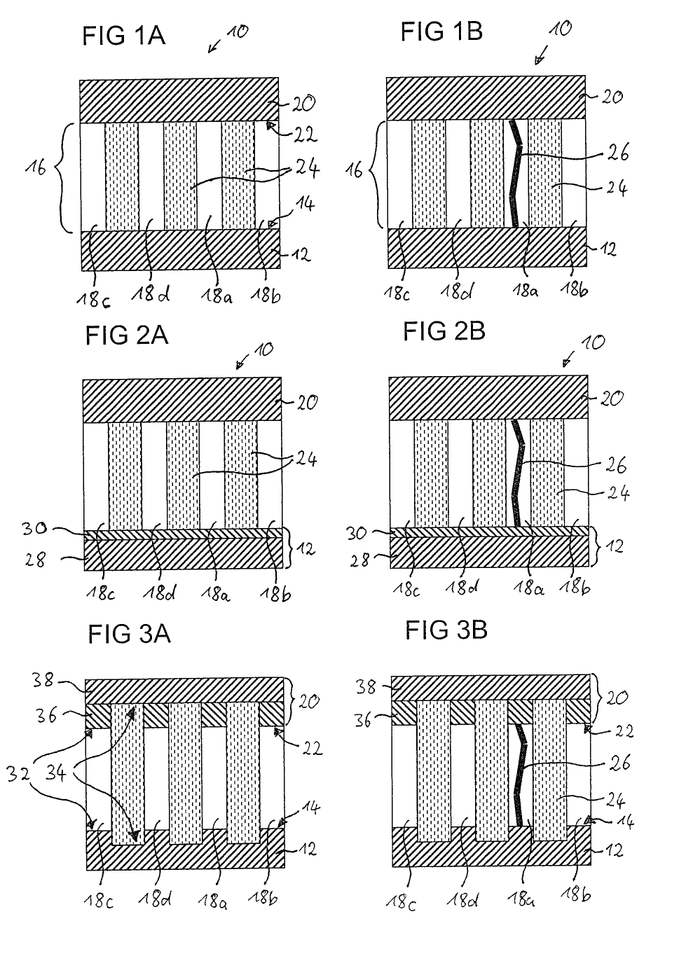

A first example of a resistive switching element which may be implemented as a non-volatile memory cell is described in connection with FIG. 1A and FIG. 1B in the following. In this example, a resistive switching element 10 may comprise a first (bottom) electrode 12 having a substantially planar first contact surface or first contact interface 14. Via the first contact interface 14 the first electrode 12 is connected to a switching region which is formed as a switching layer 16 and which comprises at least one resistive switching rod 18a. This resistive switching rod 18a is connected with its first end to the first electrode 12.

A second (top) electrode 20 is electrically connected to the switching layer 16 and, in particular, to a second end of the resistive switching rod 18a via a substantially planar second contact interface 22. In the shown example, the first contact interface 14 is substantially parallel to the second contact interface 22. Accordingly, the switching layer 16 has a substantially constant layer thickness in a direction perpendicular to the contact interfaces 14, 22. In the shown example, the resistive switching rod 18a extends with its longitudinal direction substantially perpendicular to the contact interfaces 14, 22.

As shown in FIG. 1A, the switching layer 16 comprises a thermal barrier matrix 24 such that the resistive switching rod 18a is at least partly embedded in the thermal barrier matrix 24. In particular, in the shown example the resistive switching rod 18a is enclosed by the thermal barrier matrix 24 except for the contact regions at the first and second contact interfaces 14, 22, where the resistive switching rod 18a is connected to the electrodes 12, 20. The thermal barrier matrix 24 may comprise material having a low thermal conductivity. In particular, the thermal conductivity of the thermal barrier matrix 24 may be lower than the thermal conductivity of the resistive switching rod 18a. Accordingly, diffusion of heat out of the resistive switching rod 18a during a “SET” or a “RESET” pulse is low so that only a low pulse energy is used to switch the a conductivity state of the resistive switching rod 18a for an “ON” state to an “OFF” state or vice versa.

In one aspect, the thickness of the resistive switching layer 16 and, in particular, the length of the resistive switching rod 18a may be between about 10 nm and about 100 nm or between about 30 nm and about 100 nm. An exemplary length of the resistive switching rod 18a may be about 60 nm. Nevertheless, in other examples a layer thickness or a length of the resistive switching rod 18a of more than 100 nm or less than 20 nm or even less than 10 nm may be applied. In one aspect, a transversal extent of the resistive switching rod 18a, i.e. an extent in a direction perpendicular to the longitudinal direction, is smaller than the length of the resistive switching rod 18. Accordingly, in this aspect the resistive switching rod 18a is thinner than long. In one example, the thickness of the resistive switching rod 18a may be between about 2 nm and 20 nm or between about 3 nm and 12 nm. An exemplary thickness of the resistive switching rod 18a may be about 3 nm to 7 nm.

In one example, the resistive switching rod 18a may be directly embedded in the thermal barrier matrix 24, i.e. the thermal barrier matrix 24 may be in direct contact to the resistive switching rod 18a. In another example, an intermediate layer or separation layer or isolation layer may be disposed between the resistive switching rod 18a and the thermal barrier matrix 24.

In the example shown in FIG. 1A, the resistive switching element 10 comprises a plurality of switching rods 18a, 18b, 18c, 18d each of which extends from the first electrode 12 to the second electrode 20. The resistive switching rods 18 are substantially parallel and have substantially the same length. In one example they may also have the substantially same thickness, comprise substantially the same material, and are all embedded in the thermal barrier matrix 24. In a particular example, a resistive switching element may comprise between about 5 and 200 or between about 10 an 100 resistive switching rods 18. In further examples, a switching element may comprise more than 200 or less than 5 resistive switching rods 18. In particular, an exemplary switching element may comprise only one resistive switching rod 18.

In one embodiment, it may not be required that the first and second contact interfaces 14, 22 are planar surfaces. In another example at least one of the contact surfaces 14, 22 may be a non-planar structured surface as shown in FIG. 3A, for example.

In one aspect, the at least one resistive switching rod 18 may comprise a transition metal oxinitride TMOₓN_{y}, such as NbOₓN_{y} or TaOₓN_{y}, for example. Alternatively, transition metal oxide (TMO) or any other material may be applied that exhibits at least two states having different electrical resistivity. In a high resistive state, this material such as the transition metal oxinitride may be substantially homogeneous, for example. Such a high resistivity state, according to one example, is schematically demonstrated in FIG. 1A.

When applying a current or voltage pulse between the first electrode 12 and the second electrode 20, for example, a transition from the high resistive state to a low resistive state may occur. In one example, such a transition occurs through the formation of an electrically conductive filament 26 within the at least one resistive switching rod 18a, as shown in FIG. 1B. When applying a transition metal oxinitride for the resistive switching rod 18a, for example, due to the “SET” pulse at least some of the metal-oxide bonds within the transition metal oxinitride may break and metal-nitride bonds may form instead, which may increase the electrical conductance at least with a part of the resistive switching rod 18a which part may from the electrically conductive filament 26.

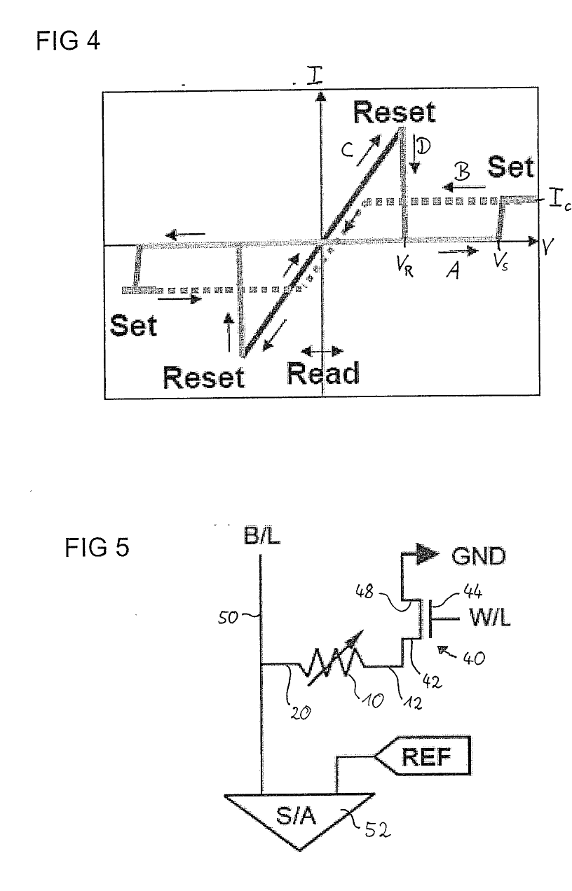

FIG. 4 represents an exemplary current versus voltage diagram (I-V) for an exemplary “SET” pulse. At the beginning, the switching device has a high resistivity, i.e. it is in its “OFF” state. When increasing the voltage V in phase A, the current (I) does not significantly increase unless the voltage (V) reaches a “SET” voltage V_{S} that may correspond to an electrical field that is high enough to trigger a transition from the high resistivity state to the low resistivity state through the breakage and rearrangement of chemical bonds within the resistive switching rod 18a, for example. In the example already mentioned, at the “SET” voltage V_{S} metal-oxide bonds may break and may be replaced by metal-nitrogen bonds, thereby increasing a conductivity of the switching element. In order to avoid damage of the switching element caused by a high current starting to flow when the switching element is set “ON” during phase A of the “SET” pulse, a current compliance may be set to a maximum current value of I_{C}. The current compliance I_{C} may, particularly, prevent an instantaneous destruction of the electrically conductive filament 26 when it is formed in phase A. Accordingly, even when reducing the voltage in phase B of the “SET” pulse shown in FIG. 4, the electrically conductive filament 26 remains stable and keeps the switching element 10 in its “ON” state.

In order to reset the switching element 10 into its “OFF” state, a “RESET” pulse may be applied between the first electrode 12 and the second electrode 20. In one example shown in FIG. 4, during the “RESET” pulse no current compliance is applied. Accordingly, when increasing the voltage in phase C of the “RESET” pulse shown in FIG. 4, the current increases with a high slope in the I-V-diagram corresponding to the low resistance of the switching element in its “ON” state. In particular, the current may exceed the value of the current compliance I_{C} set during the “SET” pulse. The current may linearly increase until the voltage reaches a critical value V_{R} which may correspond to a critical electrical power or energy applied to or deposited in the resistive switching rod 18a. This power or energy may cause a local heating of the resistive switching rod 18a and, more particularly, a heating of the conductive filament 26 and may at least partly destroy the filament 26. As a result, the switching element switches back to its high resistivity state and the current may suddenly decrease in phase D of the “RESET” pulse. The “RESET” pulse, therefore, may be completed and the voltage (V) may be returned to zero. During the “RESET” pulse the thermal barrier matrix 24 may suppress diffusion of heat out of at least a part of the resistive switching rod 18a. Accordingly, only a low electrical power or energy may be used to at least partly destroy or break the filament 26.

In one aspect the thermal barrier matrix 24 exhibits a low thermal conductance, i.e. the thermal barrier matrix 24 may serve as a barrier for heat diffusion. The thermal conductance of the thermal barrier matrix 24 and, in particular, a mean value of a thermal conductivity of material comprised in the thermal barrier matrix 24 may be lower than the thermal conductance of the at least one resistive switching rod 18. A low thermal conductance may be achieved by providing the thermal barrier matrix with a porous structure, for example. Alternatively or additionally the thermal barrier matrix 24 may comprise material having low thermal conductivity. In particular, the thermal conductivity of material applied for the thermal barrier matrix 24 may be lower than that for material used for or comprised in the at least one resistive switching rod 18.

In one aspect the thermal barrier matrix 24 comprises material having a low electric conductivity. In particular, the electric conductivity of the thermal barrier matrix 24 may be lower than that of the at least one resistive switching rod 18 in its “ON” state, i.e. in its high conductance state as shown in FIG. 1B, for example. In a further example the electric conductivity of the thermal barrier matrix 24 may even be lower than that of the at least one resistive switching rod 18 in its “OFF” state, i.e. in its low conductance state as shown in FIG. 1A, for example. This results in a rather low level of a leakage current and, therefore, a low loss of electric power or energy during a “SET” or a “RESET” pulse. Moreover, it may result in a high sensitivity of detecting or reading the switching state or storage state, since the electrical conductance between the first and the second electrode may be mainly determined or dominated by the conductance of the at least one resistive switching rod 18.

In a further aspect, the thermal barrier matrix 24 may exhibit a low dielectric constant. In particular, the thermal barrier matrix may comprise material having a low dielectric constant. In one example, the dielectric constant of the material applied for or comprised in the thermal barrier matrix 24 may be lower than the dielectric constant of material applied for the at least one resistive switching rod 18. In another example, the thermal barrier matrix 24 may comprise material having a dielectric constant of not more than 6, or not more than 4. In one particular example the thermal barrier matrix 24 may comprise material having a dielectric constant below 3.5. A small value of the dielectric constant results in a small leakage capacity and, therefore, results in low power loss or energy loss during fast or short “SET” or “RESET” cycles and allows a fast switching and a short pulse duration time.

In one example the thermal barrier matrix 24 may comprise polyimide. A polyimide from the Asahi PIMEL I-8000 series such as Asahi PIMEL I-8608M or from the Fuji Durimide® 7500 series such as Fuji Durimide® 7510 may be applied, for example.

The switching element 10 may be repeatedly switched between the states shown in FIG. 1A and FIG. 1B. In this aspect, one and the same resistive switching rod 18a of the switching element 10 may be repeatedly switched. In another aspect, the electrically conductive filament 26 may form in different resistive switching rods 18b, 18c, 18d in subsequent switching cycles, for example.

As shown in FIG. 4, in one example the “SET” pulse and the “RESET” pulse may be applied in both directions, i.e. positive or negative voltage bias may be applied. For reading the stored data, a positive and/or negative read voltage V_{O} may be applied that is smaller than both the set voltage V_{S} and the reset voltage V_{R}.

In another aspect, exemplarily shown in FIG. 2A and FIG. 2B, the first electrode 12 may comprise a first contact region 28 and an electrically conductive first diffusion barrier 30 disposed between the first contact region 28 and the first (bottom) end of the at least one resistive switching rod 18a. In another embodiment, in an analogous manner, the second electrode 20 may also comprise a second contact region and an electrically conductive second diffusion barrier disposed between the second contact region and the second (top) end of the at least one resistive switching rod 18a.

In one aspect, the first and second contact regions of contacts comprise material having a metallic electrical conductance, which does not necessarily indicate that the first and second contact regions or contacts comprise metal atoms or ions. In one example, doped semiconductor material may be applied for the first and/or second contact region.

In one aspect, the diffusion barrier layer 30 may prevent material diffusion between the contact regions 28 and the resistive switching rod 18. In another aspect, the diffusion barrier layer 30 may comprise material having a lower thermal conductivity than the contact region 28, for example. Accordingly, in this aspect the diffusion barrier layer 30 may prevent heat diffusion from the resistive switching rod 18a into the contact regions 28 and may thereby serve for keeping the pulse energies used for a “SET” pulse and a “RESET” pulse small.

Analogous to the examples described in connection with FIG. 1A and FIG. 1B, FIG. 2A represents an “OFF” state of the switching element 10, according to the second example, while FIG. 2B represents an “ON” state of the switching element 10. Switching between the “ON” and the “OFF” state may be performed analogous to the examples described with reference to FIG. 1A, 1B and FIG. 4.

According to one example, the first diffusion barrier layer 30 may comprise an electrically conductive transition metal nitride (TMN), such as niobium nitride (NbN) or titanium nitride (TiN), for example. In one aspect, a transition metal comprised in the diffusion barrier layer 30 may be the same transition metal as a transition metal comprised in the resistive switching rod 18a. For example, the resistive switching rod 18a may comprise niobium oxinitride (NbOₓN_{y}), while the diffusion barrier layer 30 may comprise niobium nitride (NbN), for example. The second diffusion barrier layer mentioned above may be implemented analogously. Nevertheless, the shown examples are not limited to such materials for the diffusion barrier layer and, instead, other electrically conductive material may be applied for the first and/or the second diffusion barrier layer.

In a further exemplary switching element 10 shown in FIG. 3A and FIG. 3B, the first contact interface 14 and the second contact interface 22 are at least partly non-planar structured surfaces. A structure of the contact interfaces may, in particular, correlate with a presence or distribution of the resistive switching rods 18, i.e. the first electrode 12 and the second electrode 20 may comprise projections 32 and recesses 34 such that the resistive switching rods 18 are in contact with the electrodes at the projections thereof, while between these contact regions the electrodes are provided with the recesses 34. Structuring of the electrodes may reduce thermal diffusion and, in particular, diffusion of heat out of the resistive switching rods 18, for example.

In one aspect the second electrode 20 may comprise a rod connection electrode 36 for each rod comprised in the resistive switching element 10 and an integration electrode 38 electrically connecting a plurality of the rod connection electrodes 36 at least within one resistive switching element. The rod connection electrode 36 may comprise metal, such as gold (Au), platinum (Pt), silver (Ag), or palladium (Pd), for example. In one example, the rod connection electrodes 36 may comprise a self-assembled structure. Such as self-assembled structure may be used for the structuring of the resistive switching rods 18 as described in more detail below.

Analogous to the examples described in connection with FIG. 1A and FIG. 1B, FIG. 3A represents an “OFF” state of the switching element 10, according to the third example, while FIG. 3B represents an “ON” state of the switching element 10. Switching between the “ON” and the “OFF” state may be performed analogous to the examples described with reference to FIG. 1A, 1B and FIG. 4.

In the exemplary schematics shown in FIG. 1 to 3 the thickness of rods is illustrated as being constant over total length of the rods and identical for all rod. Nevertheless, the resistive switching element 10 is not limited to a constant thickness of the resistive switching rods 18. In another example, the thickness of the at least one resistive switching rod 18a may vary continuously or discontinuously on its length between the first contact interface 14, i.e. the first electrode 12, and the second contact interface 22, i.e. the second electrode 20. In another aspect, a plurality of resistive switching rods 18 with different thicknesses may be applied. In yet another exemplary switching element at least one resistive switching rod 18 may be branched.

In the examples shown in FIG. 1 to 3 the at least one resistive switching rod 18a is embedded in the thermal barrier matrix 24 substantially on its whole length. Nevertheless, a resistive switching element is not limited to these examples. In another example, the at least one resistive switching rod may be only partly embedded in the thermal barrier matrix, i.e. the thermal barrier matrix may surround the resistive switching rod only along a small fraction of the total length, i.e. a short section of the resistive switching rod. In this case, an electrically conductive filament once formed within the resistive switching rod through a “SET” pulse, for example, may be broken or destroyed during a “RESET”, for example, only on a short length that is close to the “thermally embedded” section of the resistive switching rod.

In a further aspect, a memory device is provided which, in one example, may comprise at least one resistive switching element 10 as a non-volatile memory cell. One of the exemplary switching elements described with reference to FIGS. 1, 2, and 3 may serve as a part of such a non-volatile memory cell, for example. In this aspect the at least one resistive switching rod 18a may represent a storage region or a resistive storage rod of the non-volatile memory cell. All details and variations described in connection with the exemplary resistive switching elements, above, may also apply to a non-volatile memory cell according to this additional aspect.

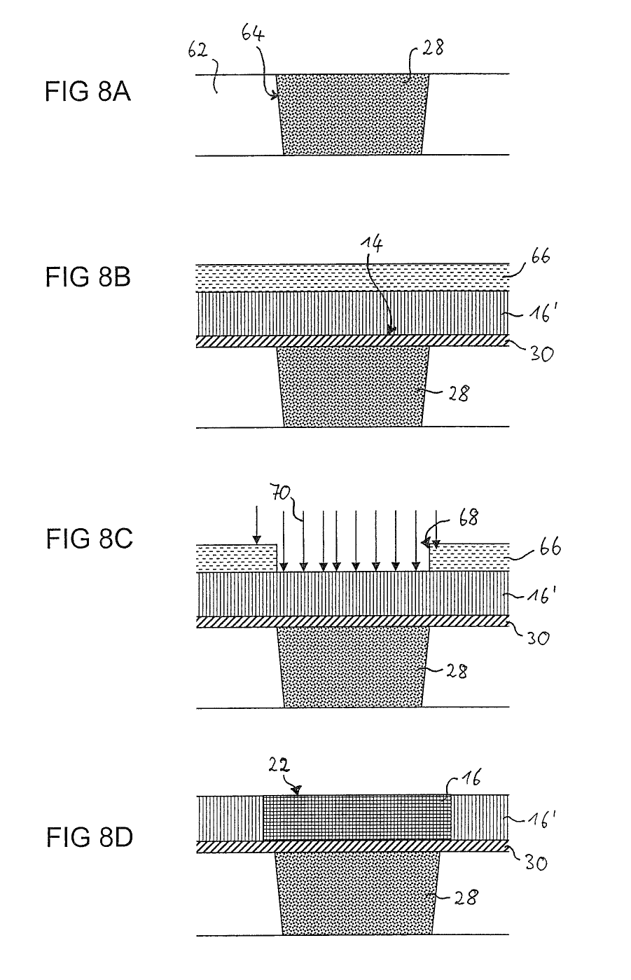

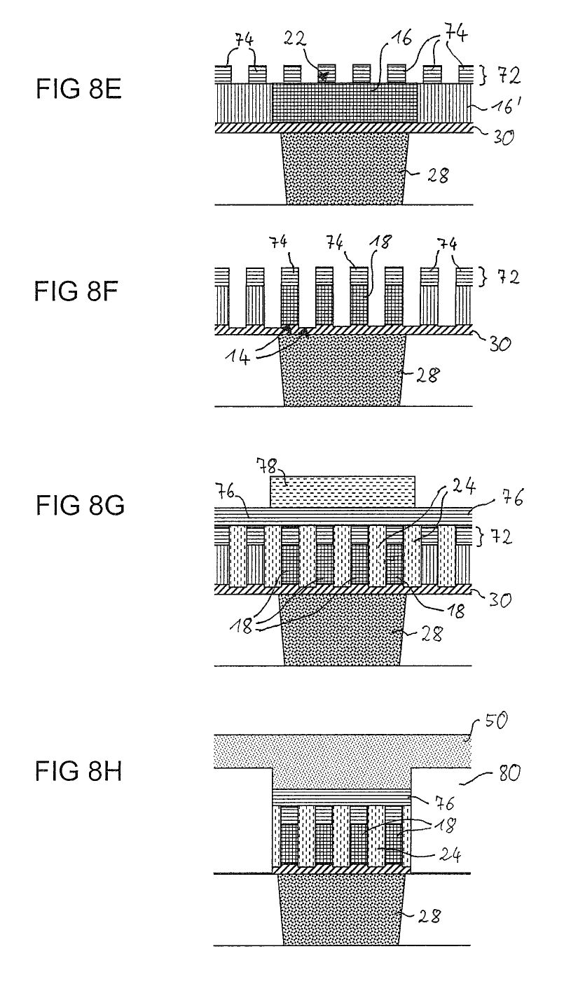

In one aspect an integrated circuit may comprise a switching element for switching between at least two states having different electrical resistance. The switching element may comprise a first electrode, a second electrode, and at least one resistive switching rod that is electrically connected to the first and the second electrode and that is at least partly embedded in a thermal barrier matrix. The switching element may be a switch that is switchable between at least two states having different electric resistance. In an exemplary integrated circuit this switch may be implemented in accordance with one of the switching elements 10 described in connection with FIGS. 1, 2, and 3, above, or with FIG. 8, below. Nevertheless, the integrated circuit is not limited to the particular examples shown above. Instead, other geometry of the first and second electrode or the resistive switching rod may be applied. Moreover, other material may be applied in the switch of the integrated circuit. In one aspect a memory module may comprise a multiplicity of integrated circuits. Said integrated circuits may comprise one or more memory cells as described herein, for example. In one particular example the memory module is stackable.

FIG. 5 shows an exemplary circuit diagram of a memory cell comprising a resistive switching element 10, according to one aspect, where the resistive switching element 10 may comprise a resistive switching rod that may be at least partly embedded in a thermal barrier matrix. Further to the resistive switching element 10, the memory cell as shown in FIG. 5 may comprise a select transistor 40 having a first source/drain region 42 which is electrically connected to the first electrode 12 of the resistive switching element 10. A gate region 44 of the select transistor 40 may be electrically connected to a word line 46 of an exemplary memory cell. In the shown example, a second source/drain region 48 of the select transistor 40 may be electrically grounded. In one aspect, the second electrode 20 of the resistive switching element 10 may be electrically connected to a bit line 50.

When opening a channel of the select transistor 40 by applying an appropriate voltage to the word line 46, the first electrode 12 of the switching element 10 is grounded and a sense amplifier 52 connected to the bit line 50 may detect a resistance value of the switching element 10. In one aspect, the sense amplifier 52 may at least distinguish between a high resistivity state and a low resistivity state of the switching element 10. This detection may represent a reading operation of the information stored in the memory cell.

According to one example shown in FIG. 5, the select transistor 40 may be a field effect transistor. The first electrode 12 may, for example, be directly connected to the first source/drain region 42 of the select transistor 40. In another example, a contact hole, such as an electrically conductive via, may provide an interposed interconnection between the first electrode 12 and the first source/drain region 42 of the select transistor 40. Nevertheless, a memory cell is not limited to the exemplary circuit as shown in FIG. 5.

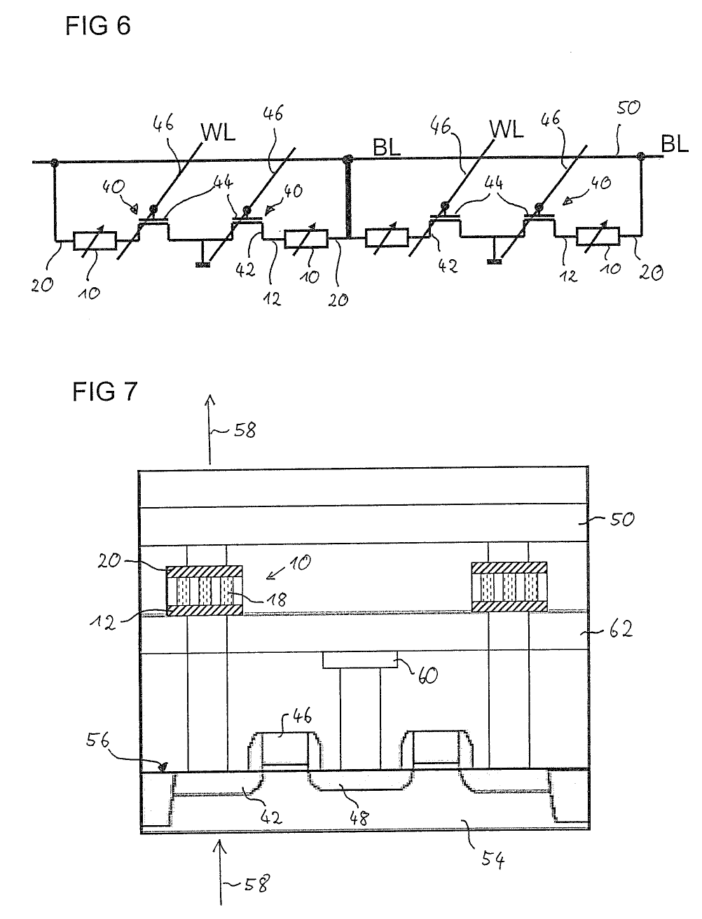

In one aspect, a memory device may comprise a plurality of non-volatile memory cells being arranged in rows and columns of at least one array. An exemplary circuit diagram is shown in FIG. 6. At least some of the memory cells may comprise a first (bottom) electrode 12, a second (top) electrode 20, at least one resistive storage rod, and a select transistor 40. Analogous to exemplary switching elements described above, the resistive storage rod may be disposed between the first (bottom) electrode 12 and the second (top) electrode 20 and may be at least partly embedded in a thermal barrier matrix. The select transistor 40 for at least some of the non-volatile memory cells may comprise a first source/drain region 42 that is electrically connected to the respective first electrode 12. In one aspect, the memory device may comprise for each row of the at least one array an electrically conductive word line 46 which is electrically connected to at least some gate contacts 44 of the select transistors 40 of the memory cells in the respective row. Furthermore, the memory device may comprise for each column of the at least one array an electrically conductive bit line 50 which is electrically connected to at least some of the second electrodes 20 of the memory cells in said column.

FIG. 7 shows a cross section of an exemplary memory device comprising a plurality of memory cells that may be arranged in at least one array. Said memory device may be implemented as a memory module. In one example the memory module may be stackable. In one aspect a memory cell of one of the FIGS. 1, 2 and 3 and according to the exemplary circuit of one of the FIGS. 5 and 6 may be implemented. In the example shown in FIG. 7, the transistor 40, such as a field effect transistor, may be implemented in or on a semiconductor substrate 54, such as a silicon on insulator (SOI), for example. The substrate 54 may comprise a substrate surface 56 and a substrate normal direction 58. The first electrode 12 is electrically connected to the first source/drain region 42 of the transistor 40, while the second source/drain region 48 is electrically grounded via a ground line 60. The transistor gate is controlled by the word line 46 which may connect a plurality of transistor gates within the same row. The bit line 50 is electrically connected to the second electrode 20 and may connect a plurality of memory cells or switching elements within the same column of the at least one array. Insulation layers such as a pre-metal dielectric or an inter-metal dielectric 62 may be applied. In one aspect as exemplarily shown in FIG. 7, the resistive switching element 10 and, particularly, the at least one resistive switching rod 18 is at least partly positioned above the first source/drain region 42 in the substrate normal direction 58 and the at least one resistive switching rod 18 may extend with its longitudinal direction substantially parallel to the substrate normal direction 58.

In another aspect an electronic device, such as a computer (e.g. a mobile computer), a mobile phone, a pocket PC, a smart phone, a PDA, for example, or any kind of consumer electronic device, such as a TV, a radio, or any house hold electronic device, for example, may comprise one or more memory cells comprising a first electrode, a second electrode, and at least one resistive switching rod that extends from the first electrode to the second electrode and that is at least partly embedded in a thermal barrier matrix. In one aspect the thermal barrier matrix may comprise thermally low conductive material such as polyimide. The electronic device may comprise a user input interface to receive data to be stored in the at least one memory cell. The input interface may comprise a keyboard, a microphone, a camera or any other sensor means. In a further aspect the electronic device comprises an output interface for outputting data stored in the at least one memory cell. The output means may comprise a display, a loudspeaker, an electronic or optical interface to an other device, or any other output means.

In one aspect, a method of fabricating a resistive switching element may comprise forming a resistive switching rod switchable between two states having different electric resistance. Furthermore, the method may comprise electrically contacting the resistive switching rod via two or more electrode means and thermally isolating at least part of the resistive switching rod. This may be achieved by embedding at least part of the resistive switching rod in a thermal barrier matrix. In one example, embedding at least part of the resistive switching rod in a thermal barrier matrix comprises arranging adjacent to the resistive switching rod material having a thermal conductivity that is lower than a thermal conductivity of the resistive switching rod. In one particular example, thermally isolating at least part of the resistive switching rod comprises arranging adjacent to the resistive switching rod material comprising polyimide.

In a further aspect, a method of fabricating the resistive memory device is described with reference to FIGS. 8A to 8H. The method may comprise, for example, providing a first electrode having a first contact surface such as the first contact interface 14; arranging a resistive switching rod with a first end thereof at the first contact surface; at least partly embedding the resistive switching rod in a thermal barrier matrix; and arranging a second electrode at a second end of the resistive switching rod. Arranging the resistive switching rod with a first end thereof at the first contact surface may comprise arranging a resistive switching layer such as the switching layer 16 at the first contact surface; and structuring the resistive switching layer to form the resistive switching rod. An exemplary structuring of the resistive switching layer comprises depositing a self-assembled shadow mask on the resistive switching layer; and removing parts of the resistive switching layer not covered by the self-assembled shadow mask. The self-assembled shadow mask may be formed from nanoparticles having a diameter of less than 10 nm and comprising metal, for example.

In one aspect, structuring the resistive switching layer comprises forming a plurality of substantially parallel resistive switching rods that extend substantially perpendicular to the first contact surface. In another aspect, embedding the resistive switching rod in the thermal barrier matrix may comprise depositing close to the resistive switching rod polyimide material.

More exemplary details are provided in the following description. As shown in FIG. 8A, a through hole 64 may be provided in a dielectric layer such as a pre-metal dielectric layer (PMD) or the inter-metal dielectric layer 62 (IMD) applying lithographic techniques, for example. This though hole 64 may be at least partly filled with the first electrode. According to one particular example as shown in FIG. 8A, the through hole 64 may be filled with the first contact region 28. In one example, the first contact region 28 may be formed by a tungsten plug (W plug). In other examples, other electrically conductive material may be applied. In one example, providing a first electrode may comprise electrically connecting said first electrode to a source and/or drain region (source/drain region) of a select transistor.

In a further exemplary step, as shown in FIG. 8B, the first diffusion barrier layer 30, a resistive switching region preparation layer 16′, and a lithographic hard mask 66 may be subsequently deposited on the first contact region 28. Accordingly, in one aspect providing the first electrode 12 may comprise depositing the electrically conductive first diffusion barrier 30 on the first contact region 28. The first diffusion barrier 30 may form the first contact interface 14. In one example, the first diffusion barrier layer 30 may comprise niobium nitride, which may be fabricated by reactive DC magnetron sputtering from a niobium target at an exemplary temperature of about 250° C. to 300° C., an exemplary sputter power density of about 2.5 to 3 W/cm², and at an exemplary pressure of 3·10⁻³ to 4·10⁻³ mbar. The percentage of nitrogen in the argon sputter gas may be about 35% to 40%, for example. In one aspect, the resistive switching region preparation layer 16′ may comprise a transition metal oxide material, such as niobium oxide (Nb₂O₅) or tantalum oxide (Ta₂O₅), for example. A niobium oxide layer according to one example may be fabricated using reactive DC magnetron sputtering from a niobium target at an exemplary temperature of about 250° C. and with an exemplary oxygen percentage of about 40% in the sputter gas. The lithographic hard mask layer 66 may comprise silicon nitride (such as Si₃N₄), for example.

According to another example, the resistive switching region preparation layer 16′ may be deposited directly on the first contact region 28 without the diffusion barrier layer 30 disposed in between.

In a further exemplary step, as shown in FIG. 8C, an implantation window 68 may be opened in the lithographic hard mask 66. The implantation window 68 may be structured by reactive ion etching, for example. In a next exemplary step, ion implantation 70 may be applied to the device. In one aspect, nitrogen ion implantation may be applied at an exemplary ion energy of about 50 keV and an exemplary flux of about 10¹⁶ cm⁻². The device may then be annealed in an inert atmosphere comprising nitrogen gas, for example. In one aspect, this may lead to the formation of a transition metal oxinitride within the resistive switching region preparation layer 16′ at least in a region below the implantation window 68, i.e. where ions have been implanted. This transition metal oxinitride may form at least in part the resistive switching region 16, as shown in FIG. 8D, for example, and it may be the basis for the formation of the at least one resistive switching rod 18, as will be describe in connection with FIGS. 8E and 8F, below. In case of a niobium oxide material used for the resistive switching region preparation layer 16′, the resulting resistive switching region may comprise niobium oxinitride.

Accordingly, in one aspect arranging the transition metal oxinitride layer, such as the exemplary switching layer or switching region 16 shown in FIG. 8D, may comprise depositing the transition metal oxide, such as the exemplary resistive switching region preparation layer 16′ shown in FIG. 8C, at the first contact interface 14. It may further comprise implanting nitrogen ions 70 in the transition metal oxide and annealing the nitrogen implanted transition metal oxide to achieve a transition metal oxinitride, such as the exemplary resistive switching region 16 shown in FIG. 8D. Before or after annealing the lithographic hard mask 66 may be removed. In case of silicon nitride used as material for the lithographic hard mask 66, it may be removed with hot phosphoric acid, for example.

In one aspect shown in FIG. 8E, a rod structuring mask 72 may be arranged at the surface such as the second contact interface 22 of the resistive switching region 16. The rod structuring mask 72 may, for example, define structures having a lateral size, i.e. a size or extent parallel to the deposition surface such as the second contact interface, below 100 nm or below 25 nm, or even below 10 nm. The rod structuring mask 72 may comprise a plurality of self-assembled nanoparticles 74. A self-assembled arrangement of nanoparticles 74, therefore, may serve as a shadow mask for further processes. In another aspect, the nanoparticles may serve as top contacts which may be at least part of the second electrode 20 for contacting the resistive switching rods 18 to be formed in subsequent processes. All known techniques of a self-assembled arrangement of nanoparticles 74 may be applied and the method of fabricating the memory device is not limited to one of these techniques. In one example, the rod structuring mask may be fabricated on the basis of diblock copolymers and metal salt precursers. In one example, the rod structuring mask 72, particularly the self-assembled nanoparticles 74, may comprise noble metal such as gold (Au), platinum (Pt), silver (Ag), or palladium (Pd). In one aspect at least some of the nanoparticles 74 may be single-crystal nanoparticles with a diameter of less than 10 nm. In one particular example the nanoparticles may have a diameter of about 3 nm to 7 nm. After the deposition of the rod structuring mask 72 the surface may be rinsed and dried in a flow of argon gas, for example.

In a further exemplary process shown in FIG. 8F, etching of at least part of the resistive switching region 16 is performed. In particular, an anisotropic etch process such as reactive plasma etching in a CH₃/O₂ atmosphere may be applied, for example. The rod structuring mask 72 serves as an etch mask in this process such that part of the resistive switching region 16 that is not covered by the rod structuring mask 72 is etched away. In one example, etching is performed such that below the nanoparticles 74 pillars or rods or studs of the resistive switching region 16 remain that substantially form the resistive switching rods 18. In one example, in areas of the resistive switching region not covered by nanoparticles 74 the resistive switching region may be removed down to the first contact interface 14. Moreover, even parts of the first diffusion barrier 30 may be removed in these areas.

In another example, etching is performed only to a depth less than the thickness of the resistive switching region 16 so that a portion of the resistive switching region may remain with a reduced layer thickness even in the uncovered areas. In this example, this remaining portion of the resistive switching region may serve as an electrode means for electrically connecting and contacting the resistive switching rod 18 and, therefore, it may be regarded as a portion of the first electrode 12. In this case no boundary surface is formed at the contact interface between the first electrode means and the resistive switching rod, since these two components are at least partly formed from the same material.

In a further exemplary process as shown in FIG. 8G, a deposition of thermal barrier material may be performed. In particular, the gaps between the resistive switching rods 18 may be filled with the thermal barrier material forming the thermal barrier matrix 24. In one example, depositing the thermal barrier matrix 24 may comprise depositing polyimide material in vacuum. In case the resistive switching rods 18 or even the nanoparticles 74 are covered by polyimide after the deposition of polyimide, excess polyimide on the surface may be removed and the nanoparticles 74 may be uncovered thereby. In one example the nanoparticles 74 are electrically conductive, such as Pt-nanoparticles, for example. In this case, removal of the excess polyimide may stop when the nanoparticles 74 are uncovered and the nanoparticles 74 may serve for electrically contacting the resistive switching rods 18. In another example, an electrically non-conductive rod structuring mask 72, and particularly electrically non-conductive nanoparticles 74, such as oxidized nanoparticles 74 may be applied. In this case, the nanoparticles 74 may be removed before depositing the polyimide or together with the excess polyimide, so that the resistive switching rods or the upper ends thereof, are laid open. Removal of the nanoparticles may also be applied in case of electrically conductive nanoparticles.

Subsequently, a structured top contact layer 76 may be formed that electrically connects the resistive switching rod 18 directly or indirectly. In one aspect, the top contact layer 76 may be at least partly comprised in the second electrode. In one aspect, the top contact layer 76 comprises platinum (Pt) and may be fabricated by DC magnetron sputtering, for example.

Subsequently, a memory stack etch mask 78 made of silicon nitride, for example, may be deposited by low pressure chemical vapor deposition (LPCVD), for example, and structured on top of the top contact layer 76. The memory stack etch mask 78 may serve as a hard mask for structuring of a memory stack by reactive ion etching of the not covered layer sequence.

In subsequent exemplary steps shown in FIG. 8H, an intermediate isolation layer 80 made of silicon oxide (such as SiO₂), for example, may be fabricated by chemical vapor deposition (CVD) and subsequent chemical-mechanical polishing (CMP). After removal of the memory stack etch mask 78, the top contact layer 76 may be electrically connected via the bit line 50, as exemplarily shown in FIG. 8H.

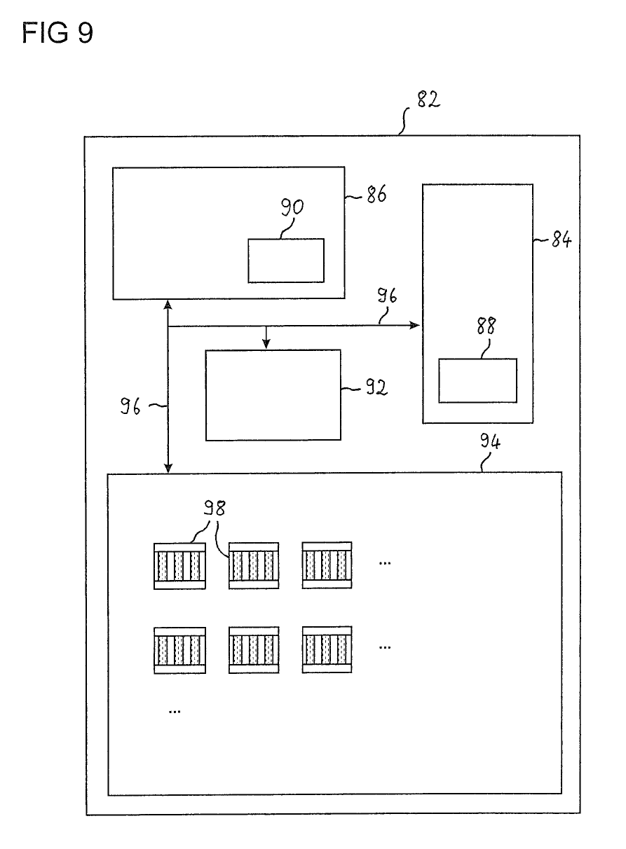

In yet another aspect exemplarily shown in FIG. 9, a computer system 82 such as a computer (e.g. a mobile computer or a server), a mobile phone, a pocket PC, a smart phone or a PDA, for example, may comprise an input apparatus 84 and an output apparatus 86. In another aspect the computer system may be implemented as any other kind of consumer electronic device, such as a TV, a radio, or any house hold electronic device, for example, or any kind of storage device, such as a chip card or memory card, for example.

In one example the input apparatus 84 may comprise input keys, a keyboard, a touch screen, a track ball a computer mouse, a joystick or any other kind of input device or input interface. In a further example, the input apparatus 84 comprises an audio input such as microphone. In yet another example, the input apparatus 84 may comprise a video input such as a camera. In the exemplary computer system 82 of FIG. 9, the input apparatus 84 comprises a wireless communication apparatus 88. The wireless communication apparatus 88 may comprise a network interface connecting the computer system 82 to a wireless network such as a local area network (LAN), a wide area network (WAN), or a telecommunications network, for example. Any type of uni-, bi-, or multi-directional wireless communication may be applied in this connection. In another aspect the input apparatus 84 may comprise a network interface connecting the computer system 82 to a wired network.

In one example, the output apparatus 86 may comprise a video output such as a display interface or a display device. In another example, the output apparatus 86 may comprise an audio device such as a speaker. In the exemplary computer system 82 of FIG. 9, the output apparatus 86 comprises a wireless communication apparatus 90. Said wireless communication apparatus 90 of the output apparatus 86 may comprise a network interface connecting the computer system 82 to a wireless network such as a local area network (LAN), a wide area network (WAN), or a telecommunications network, for example. Any type of uni-, bi-, or multi-directional wireless communication may be applied in this connection. In another aspect the output apparatus 86 may comprise a network interface connecting the computer system 82 to a wired network.

The exemplary computer system 82 of FIG. 9 further comprises a processing apparatus 92 and one or more memory components or memories 94. In one particular example, the computer system 82 may further comprise a system bus 96 that couples various system components including the memory 94 to the processing apparatus 92. The processing apparatus 92 may perform arithmetic, logic and/or control operations by accessing the memory 94, for example. The memory 94 may store information and/or instructions for use in combination with the processing apparatus 92. In one example, a basic input/output system (BIOS) storing the basic routines that helps to transfer information between elements within the computer system 82, such as during start-up, may be stored in the memory 94. The system bus 96 may be any of several types of bus structures including a memory bus or memory controller, a peripheral bus, and a local bus using any of a variety of bus architectures.

The memory 94 may comprise one or more memory cells 98. At least some of the memory cells 98 may comprise a first electrode, a second electrode, and at least one resistive storage rod that extends from the first electrode to the second electrode and that is at least partly embedded in a thermal barrier matrix comprising thermally low conductive material. In one example, one or more of the above described memory cells or one or more of the above described integrated circuits may be applied as one or more of the memory cells 98 of the memory 94. Moreover, one or more of the above described memory modules may be applied as the memory 94, for example. In one exemplary computer system 82, the memory 94 may comprise a data memory. In another example, the memory 94 may comprise a code memory. In one exemplary aspect, the memory 94 may be implemented as a data memory for storing computer readable instructions, data structures, program modules and/or other data for the operation of the computer system 82. In another aspect, the memory 94 may be implemented as a graphical memory or an input/output buffer. In one aspect the memory 94 is fixedly connected to the system bus 96 of the computer system 82. In another aspect, the memory 94 is implemented as a removable component, such as a memory card or chip card, for example.

A number of examples and implementations have been described. Other examples and implementations may, in particular, comprise one or more of the above features. Nevertheless, it will be understood that various modifications may be made. In particular, the first electrode, the second electrode and the at least one resistive switching rod are not limited to the geometry of the above describe examples. For example, the cross sectional area of the at least one resistive switching rod may vary along the length of the rod. Moreover, the thermal barrier matrix is not limited to polyimide material. Instead, other material may be applied, such as oxides, for example. Accordingly, other implementations are within the scope of the following claims.

What is claimed is:

1. An integrated circuit comprising a switching element for switching between at least two states having different electrical resistance, comprising:
a first electrode;
a second electrode; and
at least one resistive switching rod electrically connected to the first and the second electrode and that is at least partly embedded in a thermal barrier matrix.

2. The integrated circuit of claim 1, wherein the thermal barrier matrix comprises material having a high electric resistivity.

3. The integrated circuit of claim 1, wherein the thermal barrier matrix comprises material having a low dielectric constant.

4. The integrated circuit of claim 1, wherein the thermal barrier matrix comprises photo-imageable material.

5. The integrated circuit of claim 1, wherein the thermal barrier matrix comprises polyimide.

6. The integrated circuit of claim 1, wherein the at least one resistive switching rod has a length of between 10 nm and 100 nm.

7. The integrated circuit of claim 1, wherein the at least one resistive switching rod has a diameter of not more than 10 nm.

8. The integrated circuit of claim 1, wherein the at least one resistive switching rod comprises a transition metal oxinitride.

9. A memory device comprising at least one memory cell, comprising:
a first electrode;
a second electrode; and
at least one resistive storage rod that extends from the first electrode to the second electrode and that is at least partly embedded in a thermal barrier matrix comprising thermally low conductive material.

10. The memory device of claim 9, comprising a select transistor having a source/drain region that is electrically connected to the first electrode.

11. The memory device of claim 9, comprising a sense amplifier for sensing a resistance state of the at least one resistive storage rod.

12. The memory device of claim 9, comprising a plurality of resistive storage rods that extend from the first electrode to the second electrode and that are at least partly embedded in the thermal barrier matrix.

13. The memory device of claim 9, wherein the thermal barrier matrix comprises polyimide.

14. The memory device of claim 9, wherein the at least one resistive storage rod comprises transition metal oxinitride.

15. A memory device comprising a plurality of non-volatile memory cells that are arranged in rows and columns of at least one array, wherein each memory cell comprises
a first electrode;
a second electrode;
at least one resistive storage rod that extends from the first electrode to the second electrode and that is at least partly embedded in a thermal barrier matrix comprising thermally low conductive material; and
a select transistor having a source/drain region that is electrically connected to the first electrode; and wherein the memory device comprises for each row of the at least one array an electrically conductive word line which is electrically connected to at least some gate contacts of the select transistors of the memory cells in the respective row and for each column of the at least one array an electrically conductive bit line which is electrically connected to at least some of the second electrodes of the memory cells in said column.

16. The memory device of claim 15, wherein the memory cells are arranged on a semiconductor substrate having a substrate normal direction, and wherein for at least some of the memory cells the resistive storage rod is at least partly disposed above the source/drain region in substrate normal direction.

17. A memory module comprising a multiplicity of integrated circuits, wherein said integrated circuits comprise one or more memory cells comprising:
a first electrode;
a second electrode; and
at least one resistive storage rod that extends from the first electrode to the second electrode and that is at least partly embedded in a thermal barrier matrix comprising thermally low conductive material.

18. The memory module of claim 17, wherein the thermal barrier matrix comprises polyimide.

19. The memory module of claim 17, further comprising a user input interface to receive data to be stored in the at least one memory cell.

20. The memory module of claim 17, wherein the memory module is stackable.

21. A computer system comprising an input apparatus, an output apparatus, a processing apparatus and a memory, said memory comprising:
a first electrode;
a second electrode; and
at least one resistive storage rod that extends from the first electrode to the second electrode and that is at least partly embedded in a thermal barrier matrix comprising thermally low conductive material.

22. The computer system of claim 21, wherein the thermal barrier matrix comprises polyimide.

23. The computer system of claim 21, wherein one or more of the input apparatus and output apparatus comprises a wireless communication apparatus.

24. The computer system of claim 21, wherein the computer system is a server.

25. The computer system of claim 21, wherein the computer system is a mobile computer.

26. A method of fabricating a resistive switching element, the method comprising:
forming a resistive switching rod switchable between two states having different electric resistance;
electrically contacting the resistive switching rod; and
thermally isolating at least part of the resistive switching rod.

27. The method of claim 26, wherein thermally isolating at least part of the resistive switching rod comprises embedding at least part of the resistive switching rod in a thermal barrier matrix.

28. The method of claim 27, wherein embedding at least part of the resistive switching rod in a thermal barrier matrix comprises arranging adjacent to the resistive switching rod material having a thermal conductivity that is lower than a thermal conductivity of the resistive switching rod.

29. The method of claim 26, wherein thermally isolating at least part of the resistive switching rod comprises arranging adjacent to the resistive switching rod material comprising polyimide.

30. The method of claim 26, wherein the resistive switching rod is formed with a length below 100 nm and a width below 20 nm.

31. A method of fabricating a resistive memory device, the method comprising:
providing a first electrode having a first contact surface;
arranging a resistive switching rod with a first end thereof at the first contact surface;
at least partly embedding the resistive switching rod in a thermal barrier matrix; and
arranging a second electrode at a second end of the resistive switching rod.

32. The method of claim 31, wherein arranging the resistive switching rod with a first end thereof at the first contact surface comprises:
arranging a resistive switching layer at the first contact surface; and
structuring the resistive switching layer to form the resistive switching rod.

33. The method of claim 32, wherein structuring the resistive switching layer comprises:
depositing a self-assembled shadow mask on the resistive switching layer; and
removing parts of the resistive switching layer not covered by the self-assembled shadow mask.

34. The method of claim 33, wherein the self-assembled shadow mask is formed from nanoparticles having a diameter of less than 10 nm and comprising metal.

35. The method of claim 32, wherein structuring the resistive switching layer comprises forming a plurality of substantially parallel resistive switching rods that extend substantially perpendicular to the first contact surface.

36. The method of claim 31, wherein embedding the resistive switching rod in the thermal barrier matrix comprises depositing close to the resistive switching rod polyimide material.
